(19) United States
(12) Patent Application Publication
(10) Pub. No.: US 2023/0156868 A1
(43) Pub. Date: May 18, 2023

(54) SHEET-LIKE CONDUCTIVE MEMBER AND SHEET-LIKE HEATER

(71) Applicant: LINTEC CORPORATION, Tokyo (JP)

(72) Inventor: Go ONISHI, Itabashi-ku, Tokyo (JP)

(21) Appl. No.: 17/913,350

(22) PCT Filed: Mar. 16, 2021
(86) PCT No.: PCT/JP2021/010626

§ 371 Date: Sep. 21, 2022

(30) Foreign Application Priority Data
Mar. 26, 2020 (JP) 2020-056128

(51) Int. Cl. H05B 3/34

(52) U.S. Cl. CPC H05B 3/34; H05B 2203/003; H05B 2214/04

(57) ABSTRACT

A sheet-shaped conductive member includes a pseudo sheet structure including a plurality of conductive linear bodies arranged at a distance from each other, the conductive linear bodies each being in a wavy shape in a plan view of the sheet-shaped conductive member, the wavy shape being a shape where a second wave is made along an imaginary first wave, the second wave being shorter in amplitude and wavelength than the first wave.

### TECHNICAL FIELD

The present invention relates to a sheet-shaped conductive member and a sheet-shaped heater.

### BACKGROUND ART

A sheet-shaped conductive member (hereinafter, also referred to as “conductive sheet”) including a pseudo sheet structure where a plurality of conductive linear bodies are arranged at a distance from each other may be usable as members of a variety of articles, such as a heat-generating body of a heat-generating device, a material of a textile that generates heat, and a protection film for displays (an anti-crush film).

For instance, Patent Literature 1 describes, as a sheet usable as a heat-generating body, a conductive sheet including a pseudo sheet structure where a plurality of unidirectionally extending conductive linear bodies are arranged at a distance from each other. The conductive linear bodies each have a wavy first part with a wavelength λ1 and an amplitude A1 and a wavy second part with a wavelength λ2 and an amplitude A2. At least one of the wavelength λ2 and the amplitude A2 is different from the wavelength λ1 or the amplitude A1 of the first part.

### CITATION LIST

### Patent Literature(s)

Patent Literature 1: International Publication No. WO 2018/097323

### SUMMARY OF THE INVENTION

### Problem(s) to be Solved by the Invention

The conductive sheet described in Patent Literature 1 includes the conductive linear bodies having a wavy shape, which makes it possible to improve stretchability of the conductive sheet, that is, prevent damage of the conductive linear bodies when the conductive sheet is stretched. However, the stretchability needs to be further improved depending on the purpose of use of the conductive sheet.

An object of the invention is to provide a sheet-shaped conductive member and a sheet-shaped heater which have a high stretchability.

### Means for Solving the Problem(s)

According to an aspect of the invention, a sheet-shaped conductive member includes a pseudo sheet structure including a plurality of conductive linear bodies arranged at a distance from each other, the conductive linear bodies each being in a wavy shape in a plan view of the sheet-shaped conductive member, the wavy shape being a shape where a second wave is made along an imaginary first wave, the second wave being shorter in amplitude and wavelength than the first wave.

In the sheet-shaped conductive member according to the aspect of the invention, it is preferable that an expression (F1) below be satisfied:

1/20≤A₁/λ₁≤1 (F1),

where A₁ denotes an amplitude of the first wave and λ₁ denotes a wavelength of the first wave.

In the sheet-shaped conductive member according to the aspect of the invention, it is preferable that an expression (F2) below be satisfied:

1/10≤A₂/A₁≤⅗ (F2),

where A₁ denotes an amplitude of the first wave and A₂ denotes an amplitude of the second wave.

In the sheet-shaped conductive member according to the aspect of the invention, it is preferable that an expression (F3) below be satisfied:

1/21≤λ₂/λ₁≤⅓ (F3),

where λ₁ denotes a wavelength of the first wave and λ₂ denotes a wavelength of the second wave.

In the sheet-shaped conductive member according to the aspect of the invention, it is preferable that the conductive linear bodies each include at least one selected from the group consisting of a linear body including a metal wire, a linear body including a carbon nanotube, and a linear body including a yarn provided with conductive coating.

It is preferable that the sheet-shaped conductive member according to the aspect of the invention further includes a stretchable base material supporting the pseudo sheet structure.

In the sheet-shaped conductive member according to the aspect of the invention, it is preferable that the sheet-shaped conductive member is used as a heat-generating body.

A sheet-shaped heater according to another aspect of the invention includes the sheet-shaped conductive member according to the above aspect of the invention.

According to the above aspects of the invention, a sheet-shaped conductive member and a sheet-shaped heater which have a high stretchability can be provided.

### BRIEF DESCRIPTION OF DRAWING(S)

FIG. 1 schematically illustrates a sheet-shaped conductive member according to a first exemplary embodiment of the invention.

FIG. 2 shows a cross section taken along II-II in FIG. 1.

FIG. 3 schematically illustrates an example of a conductive linear body according to the first exemplary embodiment of the invention.

FIG. 4 schematically illustrates another example of the conductive linear body according to the first exemplary embodiment of the invention.

FIG. 5 schematically illustrates a sheet-shaped conductive member according to a second exemplary embodiment of the invention.

### DESCRIPTION OF EMBODIMENT(S)

### First Exemplary Embodiment

Description will be made below on the invention with reference to the drawings by citing an exemplary embodiment as an example. The invention is not limited to the contents of the exemplary embodiment. It should be noted that some portions are illustrated in an enlarged scale or a reduced scale in the drawings for the convenience of explanation.

### Sheet-Shaped Conductive Member

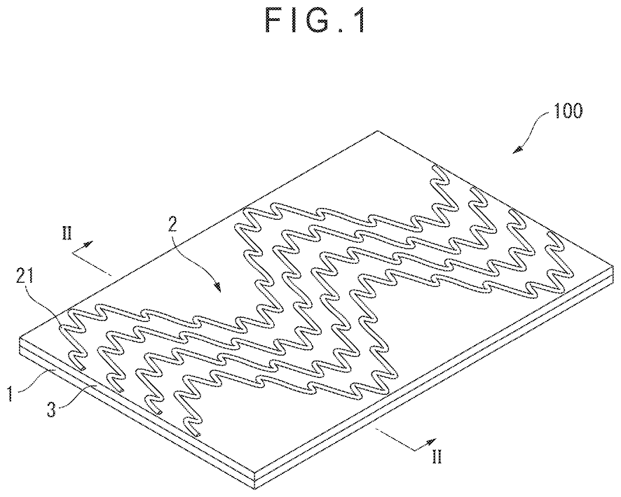

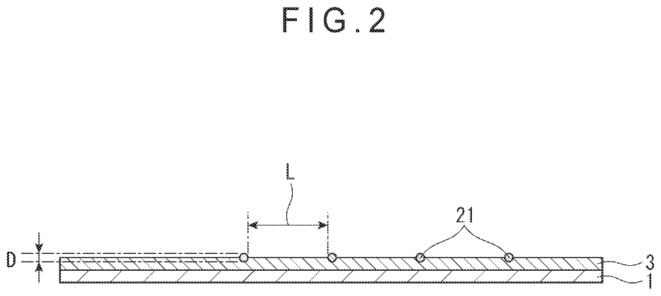

A sheet-shaped conductive member 100 according to the exemplary embodiment includes a base material 1, a pseudo sheet structure 2, and a resin layer 3 as illustrated in FIG. 1 and FIG. 2. Specifically, in the sheet-shaped conductive member 100, the resin layer 3 is stacked on the base material 1 and the pseudo sheet structure 2 is stacked on the resin layer 3. The exemplary embodiment is thus characteristic in that a conductive linear body 21 of the pseudo sheet structure 2 is in a later-described wavy shape in a plan view of the sheet-shaped conductive member 100.

### Pseudo Sheet Structure

The pseudo sheet structure 2 has a structure where a plurality of conductive linear bodies 21 are arranged at a distance from each other. In other words, the pseudo sheet structure 2 is a structure where the plurality of conductive linear bodies 21 are arranged at a distance from each other so as to form a flattened surface or a curved surface. The conductive linear bodies 21 are in a wavy shape in a plan view of the sheet-shaped conductive member 100. The pseudo sheet structure 2 thus has a structure where the plurality of conductive linear bodies 21 are arranged in a direction orthogonal to an axial direction of the conductive linear bodies 21.

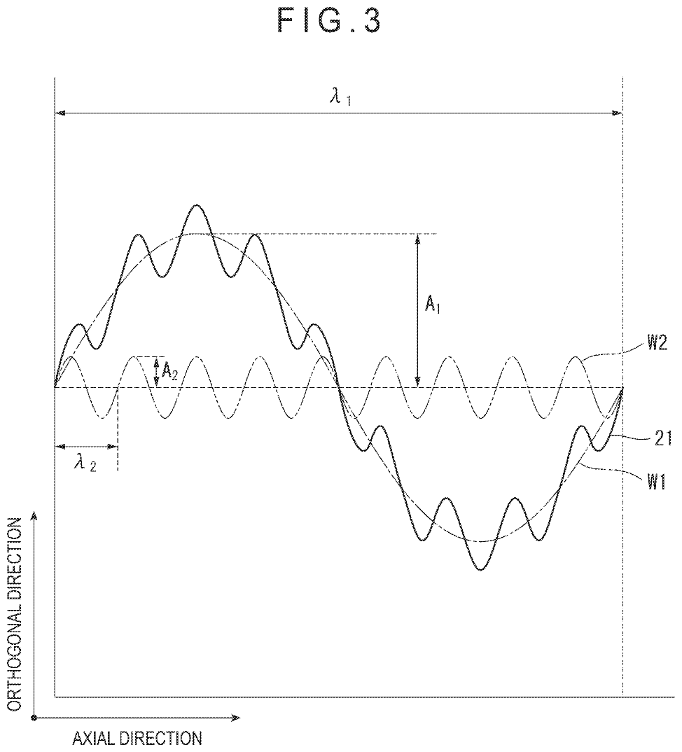

The wavy shape of the conductive linear bodies 21 is, for instance, a shape where a second wave W2 is made along an imaginary first wave W1 as illustrated in FIG. 3, the second wave W2 being shorter in amplitude and wavelength than the first wave W1. It should be noted that an expression of the wavy shape is represented by f(x)+g(x), where f(x) is an expression of the first wave W1 and g(x) is an expression of the second wave W2. Herein, a wavy shape representable by the expression f(x)+g(x) is also referred to as “synthetic composite wavy shape” in some cases.

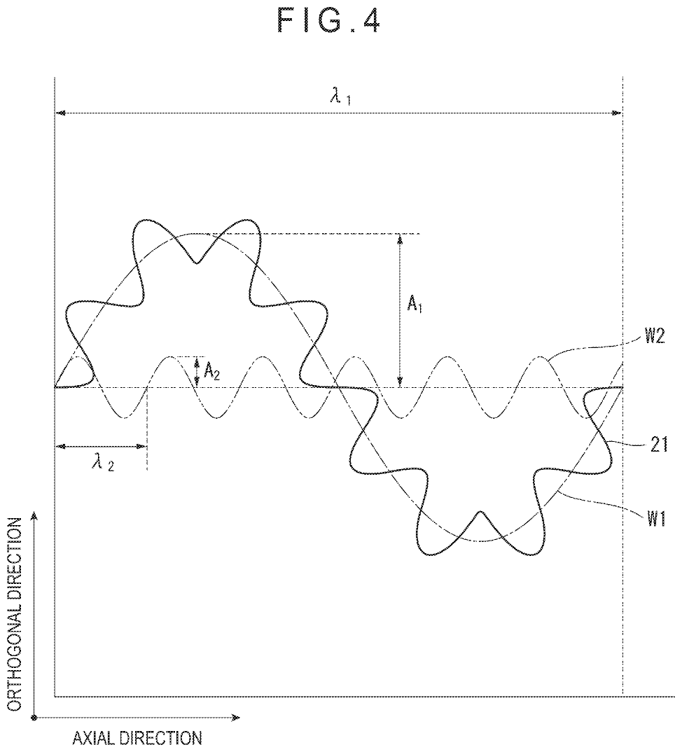

The wavy shape of the conductive linear bodies 21 may be, for instance, a shape made by adding the second wave W2 in a perpendicular direction of the first wave W1 along the imaginary first wave W1 as illustrated in FIG. 4, the second wave W2 being shorter in amplitude and wavelength than the first wave W1. Herein, a wavy shape corresponding to this wavy shape is also referred to as a “fractal composite wavy shape” in some cases.

Examples of waveforms of the first wave W1 and the second wave W2 include a sinusoidal wave, a semicircular wave, a rectangular wave, a triangular wave, and a sawtooth wave. Among the above, a sinusoidal wave or a semicircular wave is preferable in terms of stretchability of the sheet-shaped conductive member 100. Further, a semicircular wave is more preferable in terms of being able to reduce a risk of overlap or contact between the conductive linear bodies 21 during a process to shape the conductive linear bodies 21 into the wavy shape. In addition, the waveform of the first wave W1 may be the same as or different from the waveform of the second wave W2. It should be noted that a semicircular wave refers to a waveform where a semicircle protruding in a wave-crest direction (upward) and a semicircle protruding in a wave-trough direction (downward) alternately appear.

With the conductive linear bodies 21 being in a wavy shape as described above, breakage of the conductive linear bodies 21 can be reduced when the sheet-shaped conductive member 100 is stretched in the axial direction of the conductive linear bodies 21 (a forward direction of the first wave W1). In other words, the conductive linear bodies 21 are in a wavy shape and, accordingly, provide a longer path length than those in a linear shape. Further, a wavy shape as described above provides a longer path length as compared with a wavy shape of a single wave. Thus, the sheet-shaped conductive member 100 exhibits a high stretchability when stretched in the axial direction of the conductive linear bodies 21 (the forward direction of the first wave W1). It should be noted that even when the sheet-shaped conductive member 100 is stretched in a direction orthogonal to the axial direction of the conductive linear bodies 21 (hereinafter, also referred to as “orthogonal direction”), the conductive linear bodies 21 are not broken. Thus, the sheet-shaped conductive member 100 exhibits a sufficient stretchability.

A stretching rate exhibited when the sheet-shaped conductive member 100 is stretched in the forward direction of the first wave W1 of the conductive linear bodies 21 is preferably equal to or more than 50%, more preferably equal to or more than 70%, further preferably equal to or more than 100%. As long as the stretching rate is equal to or more than 50%, the sheet-shaped conductive member 100 is applicable to a curved surface of an adherend, or the like.

In addition, a stretching rate of the sheet-shaped conductive member 100 in a direction orthogonal to the forward direction of the first wave W1 of the conductive linear bodies 21 is preferably equal to or more than 50%, more preferably equal to or more than 70%, further preferably equal to or more than 100%. As long as the stretching rate is equal to or more than 50%, the sheet-shaped conductive member 100 is applicable to a curved surface of an adherend, or the like.

Here, the stretching rates of the sheet-shaped conductive member 100 according to the invention are each represented by an expression below, where A denotes a length of the sheet-shaped conductive member 100 and B denotes a length of the sheet-shaped conductive member 100 at which the conductive linear bodies 21 are broken as the sheet-shaped conductive member 100 is stretched in a predetermined direction. It should be noted that occurrence of breakage of the conductive linear bodies 21 can be determined by measuring an electric resistance value of the conductive linear bodies 21 while the sheet-shaped conductive member 100 is stretched.

Stretching Rate (%)={(B−A)/A}×100

In the exemplary embodiment, it is preferable to satisfy an expression (F1) below, where A₁ [mm] denotes the amplitude of the first wave W1 and λ₁ [mm] denotes the wavelength of the first wave W1.

1/20≤A₁/A₁≤1 (F1)

With a value of A₁/A₁ being in the above range, the stretching rate of the sheet-shaped conductive member 100 can be further improved and, additionally, a distance between adjacent ones of the conductive linear bodies 21 can be secured, enabling preventing contact between the adjacent ones of the conductive linear bodies 21. In addition, in view of the above, the value of A₁/λ₁ is more preferably in a range from 7/20 to ⅗.

The amplitude A₁ of the first wave W1 is preferably in a range from 1 mm to 200 mm, more preferably in a range from 2 mm to 50 mm. With the amplitude A₁ of the first wave W1 being in the above range, the stretching rate of the sheet-shaped conductive member 100 can be further improved.

The wavelength λ1 of the first wave W1 is preferably in a range from 1 mm to 200 mm, more preferably in a range from 2 mm to 100 mm. With wavelength λ₁ of the first wave W1 being in the above range, the stretching rate of the sheet-shaped conductive member 100 can be further improved.

In the exemplary embodiment, it is preferable to satisfy an expression (F2) below, where A₁ [mm] denotes the amplitude of the first wave W1 and A₂ [mm] denotes the amplitude of the second wave W2.

1/10≤A₂/A₁≤⅗ (F2)

With a value of A₂/A₁ being in the above range, the stretching rate of the sheet-shaped conductive member 100 can be further improved and, additionally, a distance between adjacent ones of the conductive linear bodies 21 can be secured, enabling preventing contact between the adjacent ones of the conductive linear bodies 21. In addition, in view of the above, the value of A₂/A₁ is more preferably in a range from ⅕ to ⅖.

In the exemplary embodiment, it is preferable to satisfy an expression (F3) below, where λ₁ [mm] denotes the wavelength of the first wave W1 and λ₂ [mm] denotes the wavelength of the second wave W2.

1/21≤λ₂/λ₁≤⅓ (F3)

With a value of λ₂/λ₁ being in the above range, the stretching rate of the sheet-shaped conductive member 100 can be further improved and, additionally, a distance between adjacent ones of the conductive linear bodies 21 can be secured, enabling preventing contact between the adjacent ones of the conductive linear bodies 21. In addition, in view of the above, the value of λ₂/λ₁ is more preferably in a range from 1/15 to ⅕.

A volume resistivity R of the conductive linear bodies 21 is preferably in a range from 1.0×10⁻⁹ Ω·m to 1.0×10⁻³ Ω·m, more preferably in a range from 1.0×10⁻⁸ Ω·m to 1.0×10⁻⁴ Ω·m. With the volume resistivity R of the conductive linear bodies 21 being in the above range, a surface resistance of the pseudo sheet structure 2 is likely to decrease.

The volume resistivity R of the conductive linear bodies 21 is measured as follows. A silver paste is applied to an end portion of each of the conductive linear bodies 21 and a portion 40-mm-length away from the end portion and resistances of the end portion and the portion 40-mm-length away from the end portion are measured to obtain a resistance value of the conductive linear bodies 21. Then, the above resistance value is multiplied by a cross-sectional area (unit: m²) of each of the conductive linear bodies 21 and the obtained value is divided by the above measured length (0.04 m), thereby calculating the volume resistivity of the conductive linear bodies 21.

A shape of a cross section of the conductive linear bodies 21 may be, without limitation, a polygonal shape, a flat shape, an elliptical shape, or a circular shape; however, an elliptical shape or a circular shape is preferable in terms of compatibility with the resin layer 3, etc.

In a case where the cross section of the conductive linear bodies 21 is in a circular shape, a thickness (diameter) D of the conductive linear bodies 21 (see FIG. 2) is preferably in a range from 5 μm to 3 mm. In terms of a reduction in rise in sheet resistance and an improvement in heat generation efficiency and dielectric breakdown resistance exhibited when the sheet-shaped conductive member 100 is used as a heat-generating body, the diameter D of the conductive linear bodies 21 is more preferably in a range from 8 μm to 60 μm, further preferably in a range from 12 μm to 40 μm.

In a case where the cross section of the conductive linear bodies 21 is in an elliptical shape, a length of a major axis is preferably in a range similar to that of the diameter D.

The diameter D of the conductive linear bodies 21 is an average value of diameters of the conductive linear bodies 21 measured at five spots selected at random by observing the conductive linear bodies 21 of the pseudo sheet structure 2 using a digital microscope.

A distance L between the conductive linear bodies 21 (see FIG. 2) is preferably in a range from 1 mm to 400 mm, more preferably in a range from 2 mm to 200 mm, further preferably in a range from 3 mm to 100 mm.

With the distance between the conductive linear bodies 21 being in the above range, the conductive linear bodies are rather densely arranged, which makes it possible to improve a function of the sheet-shaped conductive member 100 exhibited when the sheet-shaped conductive member 100 is used as a heat-generating body, such as equalization of distribution of temperature rise.

For the distance L between the conductive linear bodies 21, the conductive linear bodies 21 of the pseudo sheet structure 2 are observed visually or using a digital microscope and a distance between adjacent two of the conductive linear bodies 21 is measured.

It should be noted that the distance between adjacent two of the conductive linear bodies 21 refers to a length along a direction of arrangement of the conductive linear bodies 21, that is, a length between facing portions of the two conductive linear bodies 21 (see FIG. 2). In a case where the conductive linear bodies 21 are arranged at irregular distances, the distance L refers to an average value of respective distances between all the adjacent ones of the conductive linear bodies 21.

The conductive linear bodies 21 are preferably, without limitation, linear bodies including metal wires (hereinafter, also referred to as “metal wire linear bodies”). Since the metal wires have high thermal conductivity, high electric conductance, high handleability, and versatility, light transmittance is likely to be improved while a resistance value of the pseudo sheet structure 2 being reduced, when the metal wire linear bodies are used as the conductive linear bodies 21. In addition, in a case where the sheet-shaped conductive member 100 (the pseudo sheet structure 2) is used as a heat-generating body, prompt heat generation is likely to be achieved. Further, small-diameter linear bodies can be easily obtained as described above.

It should be noted that examples of the conductive linear bodies 21 include, in addition to metal wire linear bodies, linear bodies including carbon nanotubes and linear bodies including threads provided with conductive coating.

The metal wire linear bodies may each be a linear body formed of a single metal wire or a linear body formed by spinning a plurality of metal wires.

Examples of the metal wire include a wire containing a metal such as copper, aluminum, tungsten, iron, molybdenum, nickel, titanium, silver, or gold or an alloy containing two or more metals (for instance, steels such as stainless steel and carbon steel, brass, phosphor bronze, zirconium copper alloy, beryllium copper, iron nickel, nichrome, nickel titanium, kanthal, hastelloy, and rhenium tungsten). In addition, the metal wire may be a wire plated with tin, zinc, silver, nickel, chrome, nickel-chrome alloy, solder, or the like or may have a surface coated with a later described carbon material or polymer. In particular, a wire containing one or more metals selected from tungsten, molybdenum, and an alloy containing tungsten and molybdenum is preferable in terms of causing the conductive linear bodies 21 to have a low volume resistivity.

The examples of the metal wire also include a metal wire coated with a carbon material. With a metal wire coated with a carbon material, the metallic luster is reduced and thus the presence of the metal wire is likely to be less noticeable. In addition, with a metal wire coated with a carbon material, metal corrosion is also reduced.

Examples of the carbon material for coating the metal wire include amorphous carbon (e.g. carbon black, activated carbon, hard carbon, soft carbon, mesoporous carbon, and carbon fibers), graphite, fullerene, graphene, and carbon nanotubes.

A linear body including carbon nanotubes is obtained by, for instance, drawing carbon nanotubes into the form of sheet from an end portion of a carbon nanotube forest (it is a growth body obtained by causing a plurality of carbon nanotubes to grow on a substrate to be oriented in a vertical direction relative to the substrate and also referred to as “array” in some cases) and spinning a bundle of the carbon nanotubes after bundling the drawn carbon nanotube sheet. According to such a production method, a ribbon-shaped carbon nanotube linear body is obtained when the carbon nanotubes are not spun, whereas a yarn-shaped linear body is obtained when the carbon nanotubes are spun. The ribbon-shaped carbon nanotube linear body refers to a linear body having no structure where the carbon nanotubes are spun. In addition to the above, a carbon nanotube linear body can also be obtained by, for instance, spinning from a fluid dispersion of carbon nanotubes. The spinning-based production of a carbon nanotube linear body can be performed by, for instance, a method disclosed in U.S. Patent Application Publication No. 2013/0251619 (JP 2012-126635 A). In terms of achieving uniformity in diameter among carbon nanotube linear bodies, it is desirable to use a yarn-shaped carbon nanotube linear body. In terms of obtaining a highly pure carbon nanotube linear body, it is preferable to obtain a yarn-shaped carbon nanotube linear body by spinning a carbon nanotube sheet. The carbon nanotube linear body may be a linear body including two or more carbon nanotube linear bodies that are woven together. Alternatively, the carbon nanotube linear body may be a linear body including a composite of carbon nanotubes and another conductive material (hereinafter, also referred to as “composite linear body”).

Examples of the composite linear body include (1) a composite linear body containing an elemental metal or metal alloy supported on the surface of carbon nanotube forest, carbon nanotube sheet, or bundle of the carbon nanotube or on the surface of the spun linear body through vapor deposition, ion plating, sputtering, wet plating or the like during the production process of the carbon nanotube linear body, i.e., drawing a sheet-shaped carbon nanotubes from an end of a carbon nanotube forest, bundling the drawn carbon nanotube sheet, and spinning the bundle of the carbon nanotube), (2) a composite linear body produced by spinning the bundle of the carbon nanotubes together with a linear body or a composite linear body of an elemental metal or metal alloy, and (3) a composite linear body produced by weaving a linear body or a composite linear body of an elemental metal or metal alloy with a linear body or a composite linear body of carbon nanotube. It should be noted that the composite linear body of (2) may be produced by supporting a metal on the carbon nanotubes in spinning the bundle of the carbon nanotubes, in the same manner as the composite linear body of (1). Further, the composite linear body of (3) is produced by weaving two linear bodies, however, may be produced by weaving three or more linear bodies selected from the carbon nanotube linear body and a linear body or a composite linear body of an elemental metal or metal alloy as long as at least one linear body or composite linear body of an elemental metal or metal alloy is included.

Examples of the metal in the composite linear body include elemental metals such as gold, silver, copper, iron, aluminum, nickel, chrome, tin, and zinc and alloys containing at least one of these elemental metals (e.g., a copper-nickel-phosphorus alloy and a copper-iron-phosphorus-zinc alloy).

The conductive linear bodies 21 may be linear bodies including yarns provided with conductive coating. Examples of the thread include a yarn spun from a resin such as nylon and polyester. Examples of the conductive coating include a coating of metal, conductive polymer, and carbon material. The conductive coating may be formed by plating, vapor deposition, or the like. The linear body in a form of a yarn applied with a conductive coating can improve the conductivity of the linear body while keeping flexibility of the yarn. It means that the resistance of the pseudo sheet structure 2 can be easily lowered.

### Base Material

Examples of the base material 1 include synthetic resin film, paper, metal foil, nonwoven fabric, fabric, and glass film. By virtue of the base material 1, the pseudo sheet structure 2 can be directly or indirectly supported. In addition, the base material 1 is preferably a stretchable base material.

Synthetic resin film, nonwoven fabric, fabric, etc. are usable as the stretchable base material. In addition, among the above stretchable base materials, synthetic resin film or fabric is preferable and a synthetic resin film is more preferable.

Examples of a synthetic resin film include a polyethylene film, a polypropylene film, a polybutene film, a polybutadiene film, a polymethylpentene film, a polyvinyl chloride film, a polyvinyl chloride copolymer film, a polyethylene terephthalate film, a polyethylene naphthalate film, a polybutylene terephthalate film, a polyurethane film, an ethylene-vinyl acetate copolymer film, an ionomer resin film, an ethylene-(meth)acrylic acid copolymer film, an ethylene-(meth)acrylic acid ester copolymer film, a polystyrene film, a polycarbonate film, and a polyimide film. In addition to the above, the examples of the stretchable base material include cross-linked films and laminated films of the above films.

In addition, examples of paper include fine paper, recycled paper, and craft paper. Examples of nonwoven fabric include spunbonded nonwoven fabric, needlepunched nonwoven fabric, meltblown nonwoven fabric, and spunlaced nonwoven fabric. Examples of fabric include woven fabric and knitted fabric. The nonwoven fabric and the fabric as the stretchable base material are not limited to the above fabrics.

### Resin Layer

The resin layer 3 is a layer containing a resin. By virtue of the resin layer 3, the pseudo sheet structure 2 can be directly or indirectly supported. In addition, the resin layer 3 is preferably a layer containing an adhesive agent. In forming the pseudo sheet structure 2 on the resin layer 3, the adhesive agent facilitates sticking the conductive linear bodies 21 to the resin layer 3. In addition, in a case where the resin layer 3 is the layer containing the adhesive agent, the base material 1 and the conductive linear bodies 21 can be easily stuck to each other via the resin layer 3.

The resin layer 3 may be a layer including a dryable or curable resin. This gives the resin layer 3 a sufficient hardness to protect the pseudo sheet structure 2, allowing the resin layer 3 to function also as a protection film. In addition, the cured or dried resin layer 3 exhibits an impact resistance, enabling suppressing a deformation in the pseudo sheet structure 2 due to an impact.

It is preferable that the resin layer 3 be curable by an energy ray such as an ultraviolet ray, a visible energy ray, an infrared ray, or an electron ray so that the resin layer 3 can be easily cured in a short time. It should be noted that the term “curable by an energy ray” also encompasses thermal cure caused by heating with the energy ray.

Examples of the adhesive agent in the resin layer 3 include a thermosetting adhesive agent that is curable by heat, a so-called heat-seal adhesive agent that enables heat-bonding, and an adhesive agent that exhibits stickiness when wetted. However, it is preferable that resin layer 3 be curable by an energy ray for the convenience of its application. Examples of the energy-ray-curable resin include a compound having, in a molecule, at least one polymerizable double bond, among which an acrylate compound having a (meth)acryloyl group is preferable.

Examples of the acrylate compound include: a (meth)acrylate having a chain aliphatic skeleton (e.g. trimethylol propane tri(meth)acrylate, tetramethylol methane tetra(meth)acrylate, pentaerythritol tri(meth)acrylate, pentaerythritol tetra(meth)acrylate, dipentaerythritol monohydroxy penta(meth)acrylate, dipentaerythritol hexa(meth)acrylate, 1,4-butyleneglycol di(meth)acrylate, and 1,6-hexanediol di(meth)acrylate); (meth)acrylate having a cyclic aliphatic skeleton (e.g. dicyclopentanyl di(meth)acrylate, and dicyclopentadiene di(meth)acrylate), polyalkylene glycol(meth)acrylate (e.g. polyethylene glycol di(meth)acrylate); oligoester(meth)acrylate; urethane(meth)acrylate oligomer; epoxy-modified (meth)acrylate; polyether(meth)acrylate other than the above-mentioned polyalkylene glycol (meth)acrylate; and itaconate oligomer.

A weight-average molecular weight (Mw) of the energy-ray-curable resin is preferably in a range from 100 to 30000, more preferably in a range from 300 to 10000.

A single type of the energy ray curable resin or, alternatively, two or more types of the energy ray curable resins are contained in a composition of the adhesive. When two or more types of the energy-ray-curable resins are contained, a combination and a ratio of the energy ray curable resins can be selected as appropriate. Further, the energy-ray-curable resin or resins may be combined with a later-described thermoplastic resin and a combination and a ratio of the energy ray curable resin(s) and the thermoplastic resin can be selected as appropriate.

The resin layer 3 may be a sticky agent layer including a sticky agent (a pressure-sensitive adhesive agent). The sticky agent for the sticky agent layer is not specifically limited. Examples of the sticky agent include an acrylic sticky agent, a urethane sticky agent, a rubber sticky agent, a polyester sticky agent, a silicone sticky agent, and a polyvinyl ether sticky agent. Among the above, the sticky agent is preferably at least one selected from the group consisting of an acrylic sticky agent, a urethane sticky agent, and a rubber sticky agent, more preferably an acrylic sticky agent.

Examples of an acrylic sticky agent include a polymer including a constituent unit derived from alkyl (meth)acrylate having a linear alkyl group or a branched alkyl group (i.e., a polymer where at least alkyl (meth)acrylate is polymerized) and an acrylic polymer including a constituent unit derived from a (meth)acrylate having a ring structure (i.e., a polymer where at least a (meth)acrylate having a ring structure is polymerized). Here, the “(meth)acrylate” is used as a term referring to both “acrylate” and “methacrylate” and the same applies to other similar terms.

When the acrylic polymer is a copolymer, a copolymerization manner is not limited. The acrylic copolymer may be any one of a block copolymer, a random copolymer, and a graft copolymer.

The acrylic copolymer may be cross-linked by a cross-linker. Examples of the cross-linker include a known epoxy cross-linker, isocyanate cross-linker, aziridine cross-linker, and metal chelate cross-linker. In cross-linking the acrylic copolymer, a hydroxyl group, a carboxyl group, or the like, which is reactive with the above cross-linkers, can be introduced into the acrylic copolymer as a functional group derived from a monomer component of the acrylic polymer.

In a case where the resin layer 3 includes a sticky agent, the resin layer 30 may further contain the above energy-ray-curable resin in addition to the sticky agent. In addition, in a case where an acrylic sticky agent is used as the sticky agent, a compound having, in one molecule, both of a functional group reactive with the functional group derived from the monomer component of the acrylic copolymer and an energy-ray-polymerizable functional group may be used as the energy-ray-curable component. Reaction between the functional group of the compound and the functional group derived from the monomer component of the acrylic copolymer enables a side chain of the acrylic copolymer to be polymerizable by energy ray irradiation. Even in a case where the sticky agent is not the acrylic sticky agent, a component likewise having an energy-ray-polymerizable side chain may be used as a polymer component other than the acrylic polymer.

Specific examples of the thermosetting resin for the resin layer 3 include, without limitation, an epoxy resin, a phenol resin, a melamine resin, a urea resin, a polyester resin, a urethane resin, an acryl resin, a benzoxazine resin, a phenoxy resin, an amine compound, and an acid anhydride compound. One of these can be used alone or two or more thereof can be used in combination. Among the above, an epoxy resin, a phenol resin, a melamine resin, a urea resin, an amine compound, and an acid anhydride compound are preferably usable in terms of suitability for curing using an imidazole curing catalyst. Especially, an epoxy resin, a phenol resin, a mixture thereof, or a mixture with at least one selected from the group consisting of an epoxy resin, a phenol resin, a melamine resin, a urea resin, an amine compound, and an acid anhydride compound is preferably usable in terms of excellent curing characteristics.

Examples of the moisture-curable resin for the resin layer 3 include, without limitation, a resin where an isocyanate group is generated with moisture, or urethane resin, and a modified silicone resin.

In a case where the energy-ray-curable resin or the thermosetting resin is used, it is preferable that a photopolymerization initiator or a thermal polymerization initiator be used. By virtue of the use of the photopolymerization initiator or the thermal polymerization initiator, a cross-linked structure is formed, enabling the pseudo sheet structure 2 to be more securely protected.

Examples of the photopolymerization initiator include benzophenone, acetophenone, benzoin, benzoin methyl ether, benzoin ethyl ether, benzoin isopropyl ether, benzoin isobutyl ether, benzoin benzoic acid, benzoin methyl benzoate, benzoin dimethyl ketol, 2,4-diethylthioxanthone, 1-hydroxycyclohexyl phenyl ketone, benzyl diphenyl sulfide, tetramethyl thiuram monosulfide, azobisisobutyronitrile, 2-chloroanthraquinone, diphenyl(2,4,6-trimethylbenzoyl)phosphine oxide, and bis(2,4,6-trimethylbenzoyl)-phenyl-phosphine oxide.

Examples of the thermal polymerization initiator include hydrogen peroxide, peroxodisulfate (e.g. ammonium peroxodisulfate, sodium peroxodisulfate, and potassium peroxodisulfate), azo compound (e.g. 2,2′-azobis(2-amidinopropane)disulfate, 4,4′-azobis(4-cyanovaleric acid), 2,2′-azobisisobutyronitrile, and 2,2′-azobis(4-methoxy-2,4-dimethylvaleronitrile)), and organic peroxide (e.g. benzoyl peroxide, lauroyl peroxide, acetyl hydroperoxide, persuccinic acid, di-t-butylperoxide, t-butyl hydroperoxide, and cumene hydroperoxide).

One of these polymerization initiators can be used alone or two or more thereof can be used in combination.

In a case where a cross-linked structure is formed by using these polymerization initiators, the usage thereof is preferably in a range from 0.1 parts by mass to 100 parts by mass with respect to 100 parts by mass of the energy-ray-curable resin or the thermosetting resin, more preferably in a range from 1 part by mass to 100 parts by mass, particularly preferably in a range from 1 part by mass to 10 parts by mass.

The resin layer 3 is not necessarily curable but is optionally made of, for instance, a thermoplastic resin composition. Then, with a solvent being contained in the thermoplastic resin composition, the thermoplastic resin layer can be softened. This makes it easy to stick the conductive linear bodies 21 to the resin layer 3 in forming the pseudo sheet structure 2 on the resin layer 3. On the other hand, the thermoplastic resin layer can be dried to be solidified by vaporizing the solvent in the thermoplastic resin composition.

Examples of the thermoplastic resin include polyethylene, polypropylene, polyvinyl chloride, polystyrene, polyvinyl acetate, polyurethane, polyether, polyethersulfone, polyimide, and acryl resin.

Examples of the solvent include an alcohol solvent, a ketone solvent, an ester solvent, an ether solvent, a hydrocarbon solvent, an alkyl halide solvent, and water.

The resin layer 3 may contain an inorganic filler. With the inorganic filler contained, a hardness of the cured resin layer 3 can be further improved, and a thermal conductivity of the resin layer 3 is also improved.

Examples of the inorganic filler include inorganic powder (e.g., powders of silica, alumina, talc, calcium carbonate, titanium white, colcothar, silicon carbide, and boron nitride), beads of spheroidized inorganic powder, single crystal fiber, and glass fiber. Among the above, a silica filler and an alumina filler are preferable as the inorganic filler. One of the above inorganic fillers may be used alone, or two or more of the inorganic fillers may be used in combination.

Other components may be contained in the resin layer 3. Examples of other components include known additives such as an organic solvent, a flame retardant, a tackifier, an ultraviolet absorber, an antioxidant, a preservative, an antifungal agent, a plasticizer, a defoamer, and a wettability modifier.

A thickness of the resin layer 3 may be determined as desired in accordance with the purpose of use of the sheet-shaped conductive member 100. For instance, in terms of adhesiveness, the thickness of the resin layer 3 is preferably in a range from 3 μm to 150 μm, more preferably in a range from 5 μm to 100 μm.

### Method of Producing Sheet-Shaped Conductive Member

A method of producing the sheet-shaped conductive member 100 according to the exemplary embodiment is not particularly limited and the sheet-shaped conductive member 100 can be produced through, for instance, the following steps.

First, a composition for forming the resin layer 3 is applied onto the base material 1 to form a coating film. Subsequently, the coating film is dried to make the resin layer 3. Subsequently, the conductive linear bodies 21 are placed on the resin layer 3 while being arranged, thereby forming the pseudo sheet structure 2. For instance, after the resin layer 3 attached on the base material 1 is provided on an outer circumferential surface of a drum member, the conductive linear bodies 21 are fed and spirally wound on the resin layer 3 while the drum member is turned. At this time, a feeding unit of the conductive linear bodies 21 is moved such that the feeding unit performs a large reciprocating motion as a whole while repeating a small reciprocating motion in directions intersecting with respect to the axial direction of the conductive linear bodies 21 (the forward direction of the wave), whereby the conductive linear bodies 21 having the synthetic composite wavy shape where the imaginary second wave W2 is made along the imaginary first wave W1 can be formed. In addition, respective desired waveforms, amplitudes, and wavelengths of the first wave W1 and the second wave W2 of the conductive linear bodies can be obtained by selecting a turning speed of the drum member, a feeding rate of the conductive linear bodies, and movement speed and movement distance of the feeding unit as appropriate. Then, a bundle of spirally wound conductive linear bodies 21 is cut along an axial direction of the drum member. The pseudo sheet structure 2 is thus formed and placed on the resin layer 3. The resin layer 3 provided with the base material 1, on which the pseudo sheet structure 2 is formed, is removed from the drum member and thus the sheet-shaped conductive member 100 is obtained.

As another method of producing the sheet-shaped conductive member 100, the pseudo sheet structure 2 may be formed by preparing the conductive linear bodies 21 already having the wavy shape of the second wave W2, and placing the conductive linear bodies 21 on the resin layer 3 formed on the base material 1 while arranging the conductive linear bodies 21. In this case, for instance, after the resin layer 3 attached on the base material 1 is provided on the outer circumferential surface of the drum member, the conductive linear bodies 21 having the wavy shape of the second wave W2 are spirally wound onto the resin layer 3 while the drum member is turned. At this time, the feeding unit of the conductive linear bodies 21 is reciprocated along directions parallel with an axis of the drum member, whereby the conductive linear bodies 21 having the wavy shape where the imaginary second wave W2 is made along the imaginary first wave W1 is obtained. Then, a bundle of spirally wound conductive linear bodies 21 is cut along an axial direction of the drum member and thus the sheet-shaped conductive member 100 is obtained.

### Workings and Effects of First Exemplary Embodiment

According to the first exemplary embodiment, the following workings and effects are achievable.

(1) In the exemplary embodiment, the wavy shape of the conductive linear bodies 21 is a shape where the second wave W2 is made along the imaginary first wave W1, the second wave W2 being shorter in amplitude and wavelength than the first wave W1. Accordingly, the sheet-shaped conductive member 100 exhibiting a higher stretchability than a typical one is obtained.
(2) The sheet-shaped conductive member 100 according to the exemplary embodiment, which exhibits a higher stretchability, is suitably usable as a heat-generating body.

### Second Exemplary Embodiment

Next, description will be made below on a second exemplary embodiment of the invention with reference to the drawing.

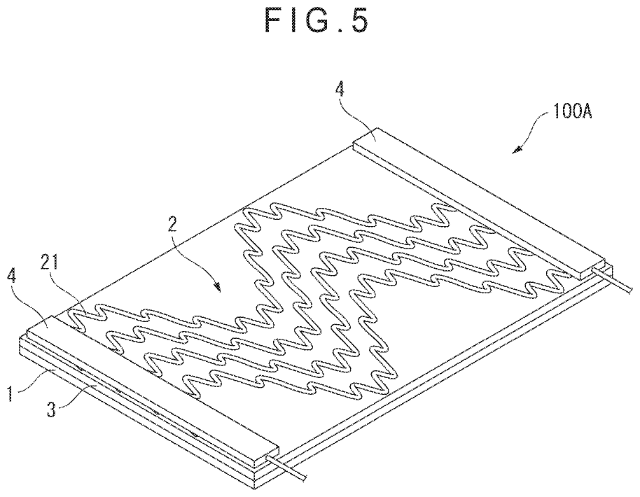

It should be noted that in the exemplary embodiment, description will be made on an example where a sheet-shaped conductive member 100A illustrated in FIG. 5 is used as a sheet-shaped heater.

The sheet-shaped conductive member 100A according to the exemplary embodiment, which includes the pseudo sheet structure 2 having a low surface resistance, is suitably usable as a sheet-shaped heater.

It should be noted that the exemplary embodiment has a similar configuration to that of the first exemplary embodiment except that an electrode 4 is attached on the pseudo sheet structure 2; therefore, description will be made on the electrode 4 and any other part that is the same as the above description will be omitted.

The electrode 4 is used for supplying electric power to the conductive linear bodies 21. The electrode 4 can be formed using a known electrode material. Examples of the electrode material include a conductive paste (e.g., a silver paste), a metal foil (e.g., a copper foil), and a metal wire. The electrode 4 is disposed on both end portions of the conductive linear bodies 21 and electrically connected thereto.

Examples of a metal of the metal foil or the metal wire include a metal such as copper, aluminum, tungsten, iron, molybdenum, nickel, titanium, silver, or gold or an alloy containing two or more metals (for instance, steels such as stainless steel and carbon steel, brass, phosphor bronze, zirconium copper alloy, beryllium copper, iron nickel, nichrome, nickel titanium, kanthal, hastelloy, and rhenium tungsten). In addition, the metal foil or the metal wire may be a foil or a wire plated with tin, zinc, silver, nickel, chrome, nickel-chrome alloy, solder, or the like.

A ratio in resistance value between the electrode 4 and the pseudo sheet structure 2 (a resistance value of the electrode 4/a resistance value of the pseudo sheet structure 2) is preferably in a range from 0.0001 to 0.3, more preferably in a range from 0.0005 to 0.1. The ratio in resistance value between the electrode and the pseudo sheet structure 2 can be determined by “the resistance value of the electrode 4/the resistance value of the pseudo sheet structure 2.” With the ratio falling within this range, abnormal heat generation at an electrode portion is reduced in a case where the sheet-shaped conductive member 100A is used as a heat-generating body. In a case where the pseudo sheet structure 2 is used as a sheet-shaped heater, only the pseudo sheet structure 2 generates heat, allowing for obtaining a sheet-shaped heater with a favorable heat generation efficiency.

The resistance values of the electrode 4 and the pseudo sheet structure 2 can be measured using a tester. The resistance value of the electrode 4 is first measured and the resistance value of the pseudo sheet structure 2 to which the electrode 4 is stuck is measured. Then, the respective resistance values of the electrode 4 and the pseudo sheet structure 2 are calculated by subtracting the measurement value of the electrode 4 from the resistance value of the pseudo sheet structure 2 to which the electrode is stuck.

A thickness of the electrode 4 is preferably in a range from 2 μm to 200 μm, more preferably in a range from 2 μm to 120 μm, particularly preferably in a range from 10 μm to 100 μm. With the thickness of the electrode falling within the above range, the electrical conductivity becomes high and the resistance becomes low, so that the resistance value relative to the pseudo sheet structure is kept low. In addition, a sufficient strength as an electrode can be obtained.

### Workings and Effects of Second Exemplary Embodiment

According to the second exemplary embodiment, workings and effects similar to the workings and effects (1) and (2) of the first exemplary embodiment are achievable.

### Modifications of Exemplary Embodiments

The invention is not limited to the above-described exemplary embodiments but includes modifications, improvements and the like as long as such modifications, improvements, and the like are compatible with an object of the invention.

For instance, the sheet-shaped conductive member 100 includes the base material 1 in the above exemplary embodiments but is not necessarily configured as in the exemplary embodiments. For instance, the sheet-shaped conductive member 100 optionally does not include the base material 1. In such a case, the sheet-shaped conductive member 100 can be stuck to an adherend in use through the resin layer 3.

The sheet-shaped conductive member 100 includes the resin layer 3 in the above exemplary embodiments but is not necessarily configured as in the exemplary embodiments. For instance, the sheet-shaped conductive member 100 optionally does not include the resin layer 3. In such a case, a knitted fabric may be used as the base material 1 and the conductive linear bodies 21 may be woven into the base material 1 to form the pseudo sheet structure 2.

### EXAMPLES

The invention will be described in further detail with reference to Examples. The invention is by no means limited to these Examples.

### Examples 1 to 19

A sticky sheet was made by applying an acrylic sticky agent (manufactured by LINTEC Corporation, product name “PK”) to have a thickness of 20 μm on a 100-μm thick polyurethane film as a base material.

A metal wire (material: tungsten) was injected onto the sticky sheet using a wire injector (manufactured by LINTEC Corporation) while a nozzle is moved, thereby arranging 30 metal wires to obtain a sheet-shaped conductive member. A cross section of the metal wires was in a circular shape and a diameter thereof was 80 μm. In addition, the metal wires having been formed in the waveform of the second wave were used.

Table 1 shows the type of the wavy shape, the waveform of the first wave, the waveform of the second wave, the value of A₁/λ₁, the value of A₂/A₁, and the value of A₂/λ₁ of the metal wires (the conductive linear bodies) of the obtained sheet-shaped conductive member. It should be noted that the wavelength λ₁ of the first wave was 4 mm and the amplitude A₁ of the first wave was 2 mm. In addition, a distance between the metal wires was 1 mm.

### Comparative 1

A sheet-shaped conductive member was obtained in the same manner as that of Example 1 except that the metal wires were arranged such that the type of the wavy shape, the waveform of the first wave, the waveform of the second wave, the value of A₁/λ₁, the value of A₂/A₁, and the value of λ₂/λ₁ reached those as shown in Table 1 below.

### Comparative 2

A sheet-shaped conductive member was obtained in the same manner as that of Example 1 except that the wavy shape was a single wavy shape (a sinusoidal wave) and the metal wires are arranged such that the value of A₁/λ₁ of the sinusoidal wave reached a value as shown in Table 1 below.

### Evaluation of Stretchability

The obtained sheet-shaped conductive members were used as samples. An SUS stainless steel-made semispherical adherend with a radius of 5 mm was prepared and each sample was stuck on a surface of the adherend and left still for one hour. Subsequently, resulting breakage of the metal wires, ease of sticking, and presence/absence of lifting and unsticking were checked. Then, the stretchability of the sheet-shaped conductive member was evaluated in accordance with the following criteria.

A: With neither breakage of the wires nor lifting and unsticking found, sticking properness (ease of sticking) was favorable.
B: Although neither breakage of the wires nor lifting and unsticking was found, working efficiency during sticking was lowered due to a difference in followability between an amplitude direction and a wavelength direction.
C: Although it was found that a part of the wires lifted to be unstuck from the resin layer, no breakage of the wires was found.
D: The wires significantly lifted to be unstuck from the resin layer and breakage of the wires occurred.

### Evaluation of Possibility of Contact Between Wires

A possibility of contact between the wires of each of the obtained sheet-shaped conductive members was evaluated in accordance with the following criteria. Table 1 shows the obtained results.

A: A distance between portions of the wires closest to each other was 0.3 mm or more.
B: A distance between portions of the wires closest to each other was less than 0.3 mm.

TABLE 1

| | | | | | | | | Possibility |
|---|---|---|---|---|---|---|---|---|
| | | Waveform of | Waveform of | | | | | of Contact |
| | Type of Wavy Shape | First Wave | Second Wave | A₁/λ₁ | A₂/A₁ | λ₂/λ₁ | Stretchability | Between Wires |
| Ex. 1 | fractal composite wavy shape | sinusoidal wave | sinusoidal wave | 1/2 | 1/10 | 1/9 | B | A |
| Ex. 2 | fractal composite wavy shape | sinusoidal wave | sinusoidal wave | 1/2 | 4/10 | 1/9 | B | A |
| Ex. 3 | fractal composite wavy shape | sinusoidal wave | sinusoidal wave | 1/2 | 5/10 | 1/9 | B | B |
| Ex. 4 | fractal composite wavy shape | sinusoidal wave | sinusoidal wave | 1/2 | 1/10 | 1/3 | B | A |
| Ex. 5 | fractal composite wavy shape | sinusoidal wave | sinusoidal wave | 1/2 | 1/10 | 1/11 | B | A |
| Ex. 6 | fractal composite wavy shape | sinusoidal wave | sinusoidal wave | 1/2 | 1/10 | 1/17 | C | A |
| Ex. 7 | fractal composite wavy shape | sinusoidal wave | sinusoidal wave | 1 | 1/10 | 1/3 | B | B |
| Ex. 8 | fractal composite wavy shape | sinusoidal wave | sinusoidal wave | 1 | 1/10 | 1/11 | A | B |
| Ex. 9 | fractal composite wavy shape | sinusoidal wave | sinusoidal wave | 1 | 1/10 | 1/17 | C | B |
| Ex. 10 | fractal composite wavy shape | sinusoidal wave | sinusoidal wave | 1/4 | 1/10 | 1/9 | C | A |
| Ex. 11 | fractal composite wavy shape | sinusoidal wave | sinusoidal wave | 1/4 | 5/10 | 1/9 | C | A |
| Ex. 12 | fractal composite wavy shape | sinusoidal wave | sinusoidal wave | 1/4 | 1/10 | 1/3 | C | A |
| Ex. 13 | fractal composite wavy shape | sinusoidal wave | sinusoidal wave | 1/4 | 1/10 | 1/17 | C | A |
| Ex. 14 | synthetic composite wavy shape | sinusoidal wave | sinusoidal wave | 1/2 | 1/10 | 1/9 | C | A |
| Ex. 15 | synthetic composite wavy shape | sinusoidal wave | sinusoidal wave | 1/2 | 4/10 | 1/9 | C | A |
| Ex. 16 | synthetic composite wavy shape | sinusoidal wave | sinusoidal wave | 1/2 | 5/10 | 1/9 | C | A |
| Ex. 17 | fractal composite wavy shape | semicircular wave | sinusoidal wave | 1/2 | 1/10 | 1/9 | A | A |
| Ex. 18 | fractal composite wavy shape | semicircular wave | sinusoidal wave | 1/2 | 4/10 | 1/9 | A | A |
| Ex. 19 | fractal composite wavy shape | semicircular wave | sinusoidal wave | 1/2 | 5/10 | 1/9 | A | A |
| Comp. 1 | single wavy shape | sinusoidal wave | — | 1/2 | — | — | D | A |
| Comp. 2 | single wavy shape | sinusoidal wave | — | 1 | — | — | D | B |

It has been confirmed from the results shown in Table 1 that the sheet-shaped conductive members obtained in Examples 1 to 19 are excellent in stretchability as compared with the sheet-shaped conductive members obtained in Comparatives 1 and 2.

It has been found from the results of Examples 1 to 6 that when the value of A₁/λ₁ is ½, the stretchability is favorable at the value of A₂/A₁ in a range from 1/10 to 5/10 and the stretchability is favorable at the value of λ₂/λ₁ in a range from ⅓ to 1/11.

It has been found from the results of Examples 14 to 16 that a fractal composite wavy shape exhibits an improved stretchability as compared with a synthetic composite wavy shape.

It has been found from the results of Examples 17 to 19 that changing the waveform of the first wave from a sinusoidal wave to a semicircular wave makes it possible to improve the stretchability and, further, lower the possibility of contact between the wires.

### EXPLANATION OF CODE(S)

1 . . . base material, 2 . . . pseudo sheet structure, 21 . . . conductive linear body, 3 . . . resin layer, 100, 100A . . . sheet-shaped conductive member

1. A sheet-shaped conductive member comprising a pseudo sheet structure comprising a plurality of conductive linear bodies arranged at a distance from each other,
the conductive linear bodies each being in a wavy shape in a plan view of the sheet-shaped conductive member,
the wavy shape being a shape where a second wave is made along an imaginary first wave, the second wave being shorter in amplitude and wavelength than the first wave.

2. The sheet-shaped conductive member according to claim 1, wherein an expression (F1) below is satisfied:
1/20≤A₁/λ₁≤1 (F1),
where A₁ denotes an amplitude of the first wave and λ₁ denotes a wavelength of the first wave.

3. The sheet-shaped conductive member according to claim 1, wherein an expression (F2) below is satisfied:
1/10≤A₂/A₁≤⅗ (F2),
where A₁ denotes an amplitude of the first wave and A₂ denotes an amplitude of the second wave.

4. The sheet-shaped conductive member according to claim 1, wherein an expression (F3) below is satisfied:
1/21≤λ₂/λ₁≤⅓ (F3),
where λ₁ denotes a wavelength of the first wave and λ₂ denotes a wavelength of the second wave.

5. The sheet-shaped conductive member according to claim 1, wherein
the conductive linear bodies each comprise at least one selected from the group consisting of a linear body comprising a metal wire, a linear body comprising a carbon nanotube, and a linear body comprising a yarn provided with conductive coating.

6. The sheet-shaped conductive member according to claim 1, further comprising a stretchable base material supporting the pseudo sheet structure.

7. The sheet-shaped conductive member according to claim 1, wherein the sheet-shaped conductive member is used as a heat-generating body.

8. A sheet-shaped heater comprising the sheet-shaped conductive member according to claim 1.
